(19) United States
(12) Patent Application Publication
(10) Pub. No.: US 2023/0309317 A1
(43) Pub. Date: Sep. 28, 2023

(54) Semiconductor Memory Device

(71) Applicant: Samsung Electronics Co., Ltd., Suwon-si (KR)

(72) Inventors: Hyuncheol KIM, Seoul (KR); Yongseok Kim, Suwon-si (KR); Kiheun Lee, Suwon-si (KR); Sangkil Lee, Suwon-si (KR); Daewon Ha, Suwon-si (KR)

(73) Assignee: Samsung Electronics Co., Ltd., Suwon-si (KR)

(21) Appl. No.: 18/059,010

(22) Filed: Nov. 28, 2022

(30) Foreign Application Priority Data
Mar. 23, 2022 (KR) 10-2022-0036266

(51) Int. Cl. H10B 53/20; H10B 53/10; H01L 23/528

(52) U.S. Cl. CPC H01L 27/11514; H01L 27/11504; H01L 23/5283

(57) ABSTRACT

A semiconductor memory device is provided. The semiconductor memory device may include a semiconductor substrate; a data storage layer including capacitors disposed on the semiconductor substrate; a switching element layer on the data storage layer and including transistors connected to the respective capacitors; and a wiring layer on the switching element layer and including bit lines connected to the transistors, The respective transistors include an active pattern, a word line that crosses the active pattern such that the word line surrounds a first sidewall, a second sidewall and a top surface of the active pattern, and a ferroelectric layer between the word line and the active patter.

### CROSS-REFERENCE TO RELATED APPLICATIONS

This U.S. non-provisional patent application claims priority under 35 U.S.C. § 119 to Korean Patent Application No. 10-2022-0036266, filed on Mar. 23, 2022, in the Korean Intellectual Property Office, the entire contents of which are hereby incorporated by reference.

### BACKGROUND

Inventive concepts relate to a semiconductor memory device, and more particularly, relates to a semiconductor memory device with improved electrical characteristics and integration.

For meeting or at least partly meeting excellent performance and/or low price demanded or expected by consumers, it is required or desired to increase integration of a semiconductor device. The integration of the semiconductor device is an important factor determining price of the semiconductor device, and thus the increased integration is particularly required or desired. In the case of a two-dimensional or planar semiconductor device, because the integration is mainly determined by an area occupied by a unit memory cell, is the integration may be greatly affected by a technique level of a fine pattern formation. Although the integration of the two-dimensional semiconductor device increases, it is still limited because ultra-expensive equipment is required for pattern reduction or miniaturization. Accordingly, semiconductor memory devices for increasing the integration, decreasing the resistance, and/or improving current driving capability of semiconductor devices have been proposed.

### SUMMARY

Some example embodiments provide a semiconductor memory device with improved integration and/or electrical characteristics.

Objectives solved by the inventive concept are not limited to the above-described objectives, and other objectives, which are not described above, may be clearly understood by those skilled in the art through the following specification.

According to some example embodiments of inventive concepts, a semiconductor memory device may include a semiconductor substrate, a data storage layer including capacitors disposed on the semiconductor substrate, a switching element layer on the data storage layer and including transistors connected to respective ones of the capacitors, and a wiring layer on the switching element layer and including bit lines connected to the transistors. Respective transistors may include an active patterna word line that crosses the active pattern such that the word line surrounds a first sidewall, a second sidewall and a top surface of the active pattern, and a ferroelectric layer between the word line and the active patter

According to some example embodiments of inventive concepts, a semiconductor memory device may include a plate electrode on a semiconductor substrate, first electrodes two-dimensionally arranged on the plate electrode, second electrodes on the first electrodes, capacitor dielectric layers between the first electrodes and the second electrodes, an active pattern having a lengthwise axis parallel to a top surface of the semiconductor substrate and connected to one of the second electrodes, a word line crossing the active pattern, a ferroelectric layer between the word line and the active pattern, and a bit line crossing the word line and connected to the active pattern.

According to some example embodiments of inventive concepts, a semiconductor memory device may include a plate electrode on a semiconductor substrate, first electrodes in a mold layer covering the plate electrode and connected to the plate electrode, second electrodes on the first electrodes, capacitor dielectric layers between the first electrodes and the second electrodes, lower contact patterns passing through a first interlayer insulating layer covering the first and second electrodes on the mold layer and respectively connected to the second electrodes, active patterns on the first interlayer insulating layer and having a lengthwise axis parallel to a top surface of the semiconductor substrate, each of the active patterns being connected to a first pair of the lower contact patterns, word lines extending in a first direction and crossing the active patterns on the first interlayer insulating layer, a ferroelectric layer between the word lines and the active patterns, upper contact patterns connected to the active patterns between the word lines, bit lines extending in a second direction and crossing the word lines, the bit lines connected to the upper contact patterns, and shielding lines extending in the second direction and respectively provided in regions between the bit lines.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a block diagram of a semiconductor memory device including a semiconductor device according to various example embodiments of inventive concepts.

FIG. 2 is a perspective view schematically illustrating a semiconductor memory device according to various example embodiments of inventive concepts.

FIG. 3 is a plan view of a semiconductor memory device according to various example embodiments of inventive concepts.

FIG. 4A is a cross-sectional view of a semiconductor memory device according to various example embodiments of inventive concepts and is a cross-sectional view taken along lines A-A′ and B-B′ of FIG. 3.

FIG. 4B is a cross-sectional view of a semiconductor memory device according to various example embodiments of inventive concepts and is a cross-sectional view taken along lines C-C′ and D-D′ of FIG. 3.

FIG. 4C is a cross-sectional view of a semiconductor memory device according to various example embodiments of inventive concepts and is a cross-sectional view taken along line E-E′ of FIG. 3.

FIGS. 5A, 5B, and 5C are enlarged views of part “P” of FIG. 4C.

FIG. 6 is a cross-sectional view of a semiconductor memory device according to various example embodiments of inventive concepts.

FIGS. 7A, 8A, 9A, 10A, 11A, and 12A are plan views illustrating a method of manufacturing a semiconductor memory device according to various example embodiments of inventive concepts.

FIGS. 7B, 8B, 9B, 10B, 11B, and 12B are cross-sectional views illustrating a method of manufacturing a semiconductor memory device according to various embodiments of inventive concepts and are cross-sectional views taken along lines A-A′ and B-B′ of FIGS. 7A, 8A, 9A, 10A, 11A, and 12A.

### DETAILED DESCRIPTION

Hereinafter, a semiconductor memory device and a method of manufacturing the same according to various example embodiments of inventive concepts will be described in detail with reference to the drawings.

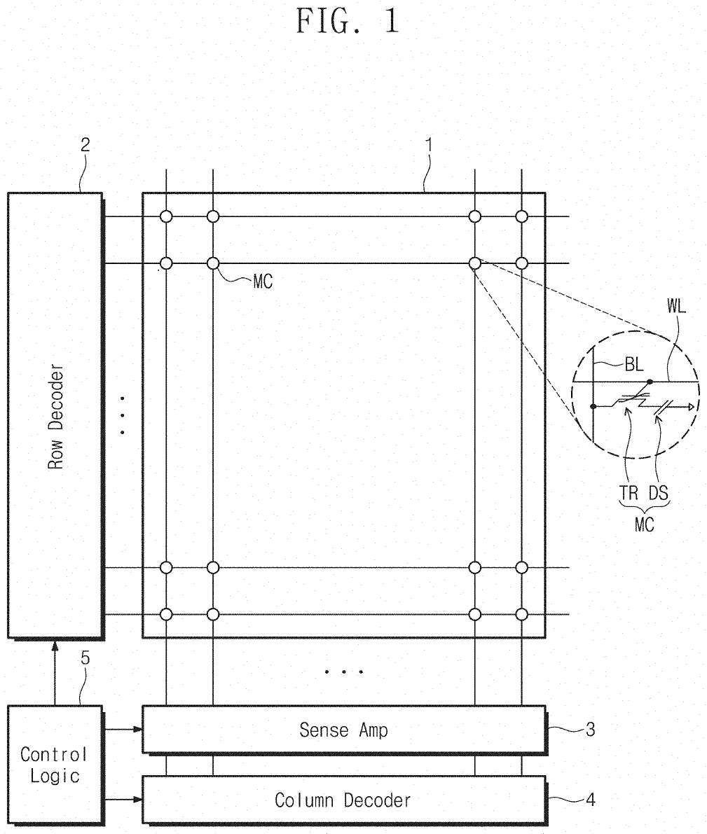

FIG. 1 is a block diagram of a semiconductor memory device including a semiconductor device according to various example embodiments of inventive concepts.

Referring to FIG. 1, a semiconductor memory device may include a memory cell array 1, a row decoder 2, a sense amplifier 3, a column decoder 4, and a control logic 5.

The memory cell array 1 may include a plurality of memory cells MC arranged two-dimensionally and/or three-dimensionally. Each of the memory cells MC may be connected between a word line WL and a bit line BL that cross each other. The memory cell array 1 may be divided into a main array and a redundancy array; however, example embodiments are not limited thereto.

Each of the memory cells MC includes a switching device TR and a data storage device DS, and the switching device TR and the data storage device DS may be electrically connected to each other, e.g. in series. The switching device TR may be connected between the data storage device DS and the bit line BL, and may be controlled by the word line WL.

The switching device TR may be or may include a field effect transistor (FET) including a ferroelectric. The switching device TR may be an NMOS transistor, or alternatively may be a PMOS transistor; however, example embodiments are not limited thereto. A gate electrode of the transistor may be connected to the word line WL, and drain/source terminals (or source/drain terminals) of the transistor may be connected to the bit line BL and the data storage device DS, respectively.

The data storage device DS may be implemented as a capacitor, a magnetic tunnel junction pattern, or a variable resistor. In various example embodiments, the data storage device DS may include a capacitor, a first electrode of the capacitor may be connected to the drain terminal of the switching device TR, and a second electrode of the capacitor may be grounded.

The row decoder 2 may decode an input address, such as an externally input address and thus select one of the word lines WL of the memory cell array 1. The address decoded by the row decoder 2 may be provided to a row driver (not shown), and the row driver may provide a certain voltage to the selected word line WL and the unselected word line WL, respectively, in response to a control of control circuits. The voltage applied to the selected word line WL and to the unselected word line WL may be voltages determined or based on a threshold voltage of the switching device TR.

The sense amplifier 3 may sense, amplify, and output a voltage difference between the selected bit line BL and a reference bit line, depending on an address decoded from the column decoder 4.

The column decoder 4 may provide a data transmission path between the sense amplifier 3 and an external device (e.g., a memory controller). The column decoder 4 may decode an externally input address and select one of the bit lines BL.

The control logic 5 may generate control signals for controlling operations of writing and/or reading data into the memory cell array 1.

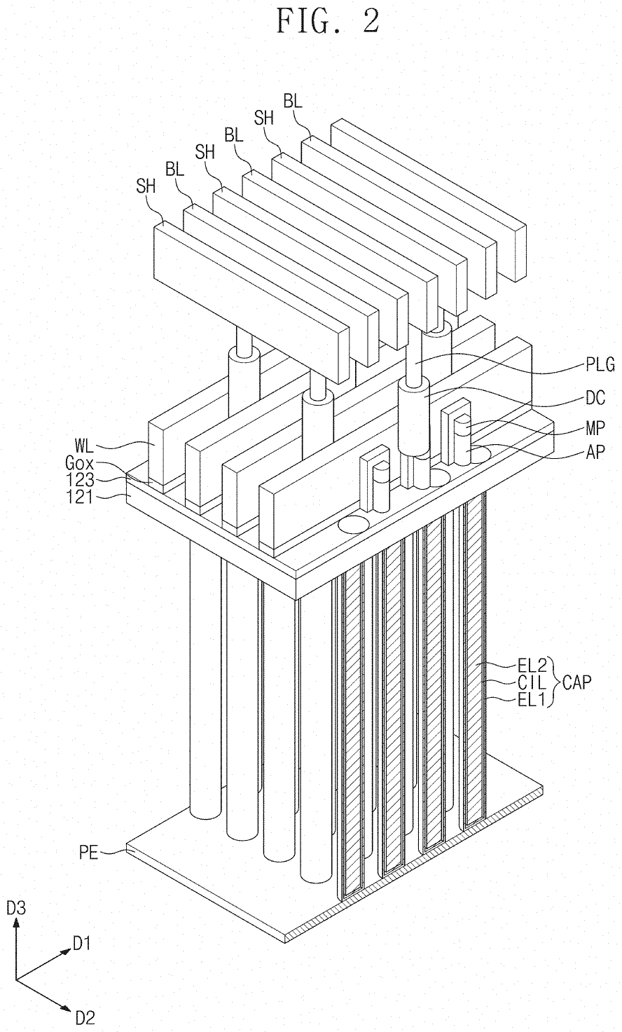

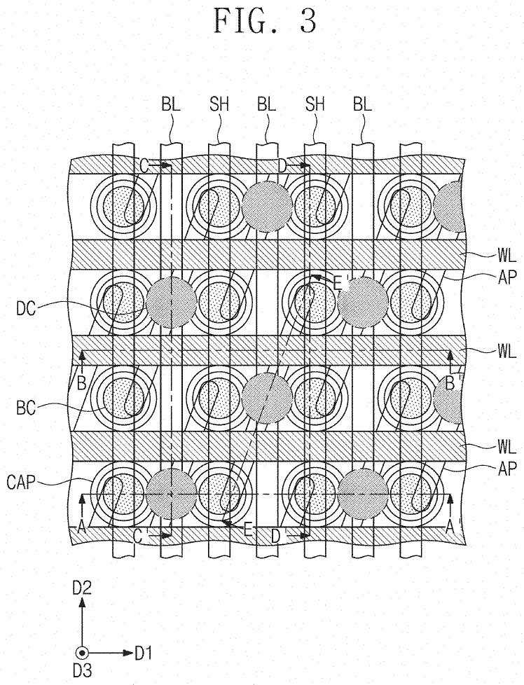

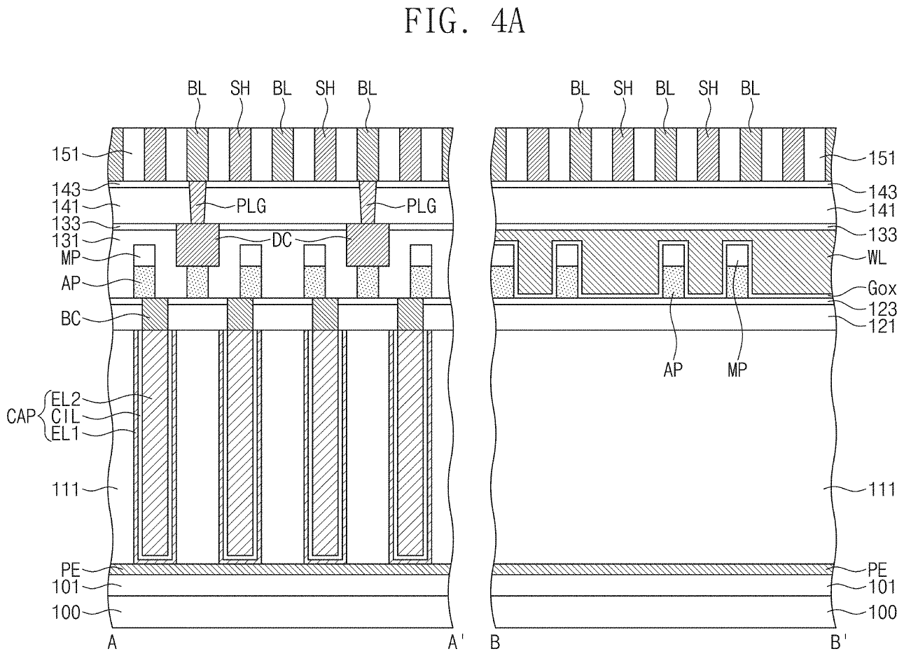

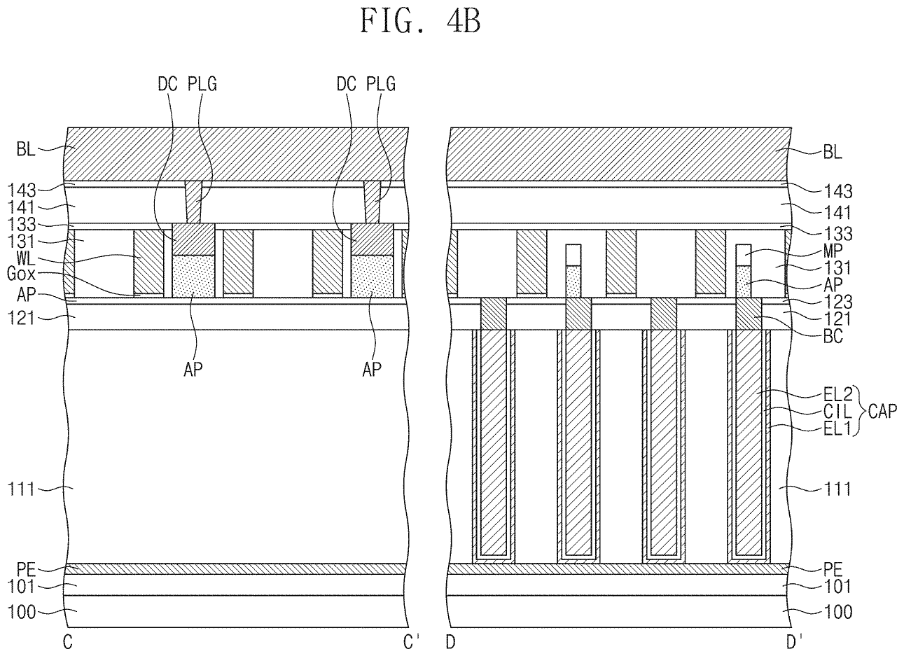

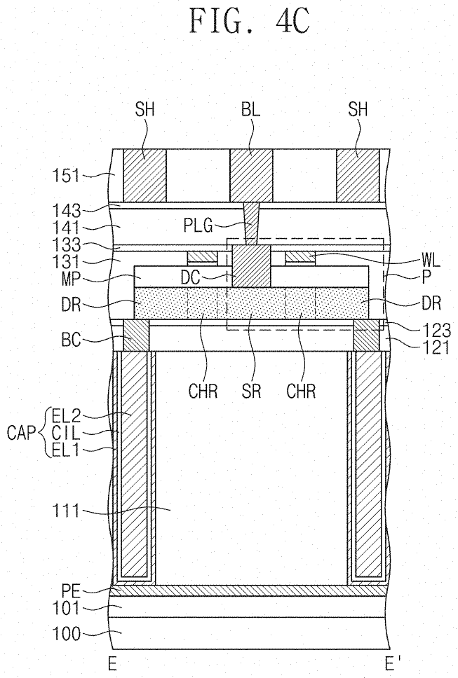

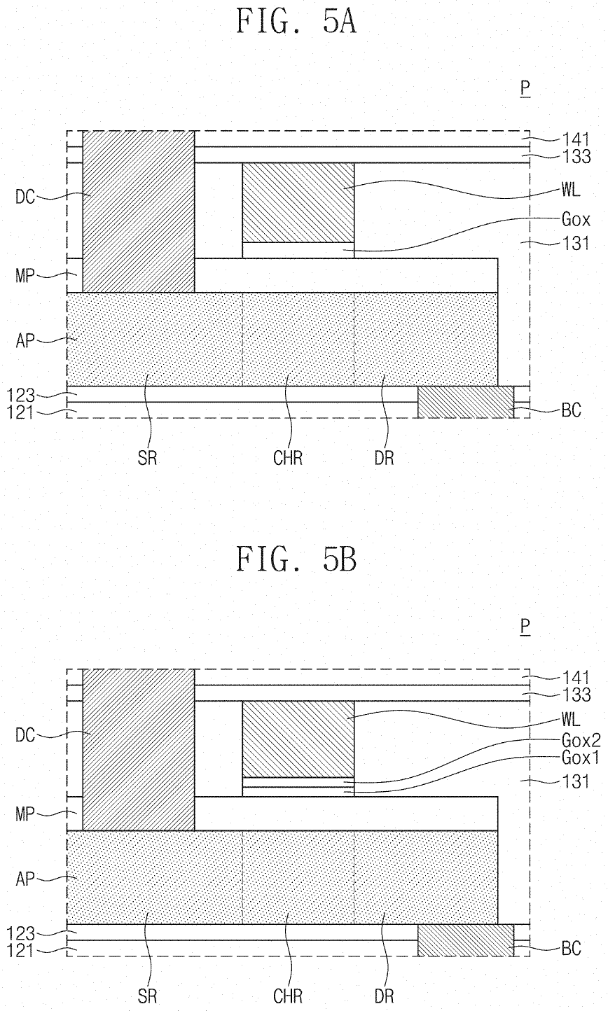

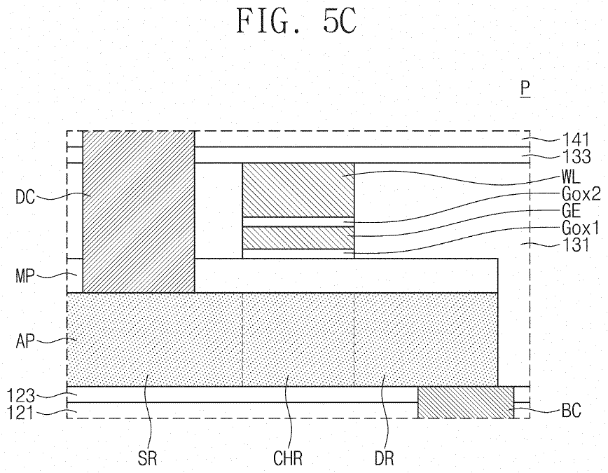

FIG. 2 is a perspective view schematically illustrating a semiconductor memory device according to various example embodiments of inventive concepts. FIG. 3 is a plan view of a semiconductor memory device according to various example embodiments of inventive concepts. FIG. 4A is a cross-sectional view of a semiconductor memory device according to various example embodiments of inventive concepts and is a cross-sectional view taken along lines A-A′ and B-B′ of FIG. 3. FIG. 4B is a cross-sectional view of a semiconductor memory device according to various example embodiments of inventive concepts and is a cross-sectional view taken along lines C-C′ and D-D′ of FIG. 3. FIG. 4C is a cross-sectional view of a semiconductor memory device according to various example embodiments of inventive concepts and is a cross-sectional view taken along line E-E of FIG. 3. FIGS. 5A, 5B, and 5C are enlarged views of part “P” of FIG. 4C.

Referring to FIGS. 2, 3, 4A, 4B, and 4C, capacitors CAP may be provided on a lower insulating layer 101 covering a semiconductor substrate 100. In detail, a plate conductive layer PE may be placed or disposed on the lower insulating layer 101. The plate conductive layer PE may have a plate shape extending in a first direction D1 and a second direction D2 intersecting the first direction D1. Here, the first and second directions D1 and D2 may be parallel to a top surface of the semiconductor substrate 100. The plate conductive layer PE may include, for example or include, doped polysilicon, metal, conductive metal nitride, conductive metal silicide, conductive metal oxide, or a combination thereof. The plate conductive layer PE may be formed of or include, for example, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but is not limited thereto.

A plurality of memory elements such as capacitors CAP may be disposed on the plate conductive layer PE. The capacitors CAP may be commonly connected to the plate conductive layer PE.

In detail, a lower mold layer 111 may be disposed on the plate conductive layer PE, and the lower mold layer 111 may have a plurality of holes that are two-dimensionally arranged. The lower mold layer 111 may be formed of or include, for example, a high-density plasma (HDP) oxide layer, TetraEthylOrthoSilicate (TEOS), Plasma Enhanced TetraEthylOrthoSilicate (PE-TEOS), O₃-Tetra Ethyl Ortho Silicate (O₃-TEOS), Undoped Silicate Glass (USG), PhosphoSilicate Glass (PSG), Borosilicate Glass (BSG), BoroPhosphoSilicate Glass (BPSG), Fluoride Silicate Glass (FSG), Spin On Glass (SOG), Tonen SilaZene (TOSZ), or a combination thereof.

The capacitors CAP may be provided in the holes of the lower mold layer 111. Each of the capacitors CAP may include a first electrode EL1, a second electrode EL2 on the first electrode ELL and a capacitor dielectric layer CIL between the first and second electrodes EL1 and EL2.

In detail, the plurality of first electrodes EL1 may pass through the lower mold layer 111 and be disposed on the plate conductive layer PE, and the first electrodes EL1 may be commonly connected to the plate conductive layer PE. Each of the first electrodes EL1 may include a horizontal part on the plate conductive layer PE and a sidewall part vertically extending from the horizontal part. For example, each of the first electrodes EL1 may have a cylindrical shape or a prismatic shape or a tube shape or a tapered cylindrical shape.

The first electrodes EL1 may be arranged in the first direction D1 and the second direction D2 on the plate conductive layer PE. The first electrodes EL1 may be spaced apart from one another at regular intervals in the first direction D1 and may be spaced apart from one another at regular intervals in the second direction D2. For example, the first electrodes EL1 may be arranged in a matrix manner on the plate conductive layer PE, such as but not limited to a rectangular or square matrix, or a honeycomb or hexagonal or regular hexagonal matrix.

The capacitor dielectric layer CIL may cover inner walls of the first electrodes EL1 with a uniform thickness. The capacitor dielectric layer CIL may include any single layer selected from a combination consisting of or including, for example, a metal oxide such as HfO₂, ZrO₂, Al₂O₃, La₂O₃, Ta₂O₃, and TiO₂, and a perovskite-structured dielectric material such as SrTiO₃ (STO), (Ba,Sr)TiO₃ (BST), BaTiO₃, PZT, PLZT, or a combination of these layers.

The second electrodes EL2 may fill, e.g. conformally fill, the insides of the first electrodes EL1 in which the capacitor dielectric layer CIL is formed, respectively. Each of the second electrodes EL2 may have a pillar or prismatic shape. Like the first electrodes ELL the second electrodes EL2 may be arranged in a matrix manner in a plan view. The second electrodes EL2 may include the same metal material as the material of the first electrodes EL1; however, example embodiments are not limited thereto.

The first and second electrodes EL1 and EL2 may include, for example, a refractory metal layer such as one or more of cobalt, titanium, nickel, tungsten and molybdenum and/or a metal nitride layer such as a titanium nitride layer (TiN), a titanium silicon nitride layer (TiSiN), a titanium aluminum nitride layer (TiAlN), a tantalum nitride layer (TaN), a tantalum silicon nitride layer (TaSiN), a tantalum aluminum nitride layer (TaAlN), and a tungsten nitride layer (WN).

A first interlayer insulating layer 121 may be disposed on the lower mold layer 111 and on the capacitors CAP, and a first etch stop layer 123 may be disposed on the first interlayer insulating layer 121. The first etch stop layer 123 may be formed of an insulating material having etch selectivity, e.g. a slower etch rate, with respect to the first interlayer insulating layer 121, and may be thinner than the first interlayer insulating layer 121.

The first interlayer insulating layer 121 may include at least one of a silicon oxide layer and a low-k layer. The first etch stop layer 123 may include, for example, at least one of a silicon oxide layer, a silicon nitride layer, a silicon oxynitride layer, or a low-k layer.

A lower contact patterns BC may pass through the first interlayer insulating layer 121 and the first etch stop layer 123 to be respectively connected to the second electrodes EL2 of the capacitors CAP. For example, the lower contact patterns BC may be in contact with top surfaces of the second electrodes EL2, respectively. The lower contact patterns BC may be arranged in a matrix manner, such as a rectangular or square matrix manner, or a triangular or honeycomb matrix manner, in a plan view. The lower contact patterns BC may include one of a doped semiconductor material (e.g., doped silicon and/or doped germanium, etc.), a conductive metal nitride (e.g., titanium nitride and/or tantalum nitride, etc.), a metal (e.g., one or more of tungsten, titanium, tantalum, etc.), and a metal-semiconductor compound (e.g., one or more of tungsten silicide, cobalt silicide, titanium silicide, etc.).

Active patterns AP may be disposed on the first etch stop layer 123 to be spaced apart from one another. Each of the active patterns AP may have a lengthwise axis in a direction parallel to the top surface of the semiconductor substrate 100, and the lengthwise axis of each active pattern AP may extend in a diagonal direction with respect to the first direction D1 and the second direction D2 crossing each other. Each of the active patterns AP may have a bar shape on the first etch stop layer 123. Each of the active patterns AP may have a certain height on the first etch stop layer 123, have a certain length along the lengthwise axis, and have a certain width along a minor axis. A width of each active pattern AP may be smaller than a width of the lower contact pattern BC. For example, the active patterns AP may have the lengthwise axis in the diagonal direction and be arranged in a zig-zag manner, but inventive concepts are not limited thereto, and the shape and arrangement of the active patterns AP may be variously modified.

The active patterns AP may be formed of a semiconductor material, for example, a semiconductor material such as one or more of silicon (Si), germanium (Ge), silicon-germanium (SiGe), indium gallium zinc oxide (IGZO), or a two-dimensional semiconductor material.

Each of the active patterns AP may be in contact with a pair of lower contact patterns BC. A first and second end of each active pattern AP may be in contact with top surfaces of the lower contact patterns BC, and a central part of each active pattern AP may be disposed between two lower contact patterns BC adjacent to each other in the first direction D1.

In detail, referring to FIGS. 4C and 5A, each of the active patterns AP may include a common source region SR, drain regions DR spaced apart from the common source region SR to be provided at both ends of the common source region SR, and a channel region CHR provided between the common source region SR and each drain region DR. The drain regions DR may be in contact with parts of the lower contact patterns BC. For example, a part of a bottom surface of each active pattern AP may be in contact with the lower contact pattern BC, directly. The common source region SR may be in contact with parts of upper contact patterns DC. For example, a part of the top surface of each active pattern AP may be in contact with the upper contact pattern DC.

Referring back to FIGS. 4A, 4B, and 4C, mask patterns MP having the same shape as the active patterns AP may be disposed on the active patterns AP. The mask patterns MP may be formed of an insulating material, and may include, for example, one or more of a silicon oxide layer, a silicon nitride layer, or a silicon oxynitride layer. As another example, the mask patterns MP may be omitted, and a ferroelectric layer Gox and/or a gate dielectric layer may cover top surfaces of the active patterns AP.

The word lines WL may extend in the first direction D1 across the active patterns AP on the first etch stop layer 123. According to various example embodiments, a pair of word lines WL may be provided on each active pattern AP.

The word lines WL may extend in the first direction D1 while enclosing both sidewalls of the active patterns AP and top surfaces of the mask patterns MP. In addition, each of the word lines WL may have a first thickness on the active pattern AP and a second thickness greater than the first thickness on the first etch stop layer 123. Top surfaces of the word lines WL may be positioned at a higher level than top surfaces of the mask patterns MP.

The word lines WL may include, for example, doped polysilicon, metal, conductive metal nitride, conductive metal silicide, conductive metal oxide, or a combination thereof. The word lines WL may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but is not limited thereto. The word lines WL may include a single layer or multiple layers of the aforementioned materials. In some example embodiments, the word lines WL may include a two-dimensional semiconductor material, for example, a two-dimensional semiconductor material may include graphene, carbon nanotube, or a combination thereof.

The ferroelectric layer Gox may be disposed between the word lines WL and the active patterns AP and between the word lines WL and the first etch stop layer 123. Referring to FIGS. 4A and 5A, the ferroelectric layer Gox may have a uniform thickness on sidewalls of the active patterns AP and on top surfaces of the mask patterns MP.

According to various example embodiments, the ferroelectric layer Gox may be formed of a ferroelectric material having spontaneous electrical polarization (e.g., a spontaneous dipole) in a state where an external electric field is not applied. Alternatively or additionally, the ferroelectric material may have a hysteresis characteristic in a polarization value with respect to a voltage change. For example, the ferroelectric material may have a negative capacitance in a specific operation, and a subthreshold swing value of the transistor due to the characteristics may be reduced. Accordingly, in the transistor, an off current (e.g., leakage current) may be reduced, and/or a gate voltage may be reduced. Therefore, standby power and/or operation power of the transistor may be reduced.

The ferroelectric layer Gox may include, for example, HfO₂, Si-doped HfO₂ (HfSiO₂), Al-doped HfO₂ (HfAlO₂), HfSiON, HfZnO, HfZrO₂, ZrO₂, ZrSiO₂, HfZrSiO₂, ZrSiON, LaAlO₂, or HfDyO₂, HfScO₂.

The material properties of the ferroelectric layer Gox may be affected by a crystal phase of the ferroelectric material. In various example embodiments, the ferroelectric layer Gox may be formed after formation of the capacitors in which a high-temperature thermal process is performed, and thus thermal budget of the ferroelectric layer Gox may be reduced, and a change in material properties of the ferroelectric layer Gox may be reduced or minimized. In various example embodiments, by having the word line WL and the bit line BL above or over the capacitors CAP, there may be a reduction in thermal budget affecting the ferromagnetic layer Gox. The semiconductor device may be or may include a plurality of one transistor, one capacitor (1T1C) memory cells, wherein the bit line BL and/or the word line WL are over or above the capacitor CAP. The capacitor CAP may not be buried as a deep trench in the substrate 100, but may be on top of the substrate 100.

Meanwhile, referring to FIGS. 4A, 4B, 4C, and 5B, a gate dielectric layer Gox1 may be interposed between the sidewalls of the active patterns AP and a ferroelectric layer Gox2 and between the top surface of the mask pattern MP and the ferroelectric layer Gox2. The gate dielectric layer Gox1 may be formed of one or more of a silicon oxide layer, a silicon oxynitride layer, a high-k dielectric layer having a higher dielectric constant than a dielectric constant of the silicon oxide layer, or a combination thereof.

As another example, referring to FIGS. 4A, 4B, 4C, and 5C, a ferroelectric layer Gox2 may be disposed between the word lines WL and the active patterns AP, and the gate dielectric layer Gox1 may be disposed between the ferroelectric layer Gox2 and the active patterns AP. In addition, an intermediate electrode GE may be disposed between the gate dielectric layer Gox1 and the ferroelectric layer Gox2. The intermediate electrode GE may include, for example, one or more of a doped semiconductor material (e.g., doped silicon, doped germanium, etc.), a conductive metal nitride (e.g., titanium nitride, tantalum nitride, etc.), a metal (e.g., tungsten, titanium, tantalum, etc.), and a metal-semiconductor compound (e.g., tungsten silicide, cobalt silicide, titanium silicide, etc.). As described above, the ferroelectric layer Gox2 may be disposed between the word lines WL and the intermediate electrode GE, and therefore operating characteristics of the transistor including the ferroelectric layer Gox2 may be further improved.

A second interlayer insulating layer 131 may fill between the word lines WL on the first etch stop layer 123. A top surface of the second interlayer insulating layer 131 may be positioned at substantially the same level as or lower level than the top surfaces of the word lines WL. The second interlayer insulating layer 131 may cover the top surface of the mask pattern MP.

A second etch stop layer 133 may be disposed on the second interlayer insulating layer 131, and the second etch stop layer 133 may cover the top surfaces of the word lines WL. The second etch stop layer 133 may be formed of or include an insulating material different from the insulating material of the second interlayer insulating layer 131.

The upper contact pattern DC may be in contact with the top surface of each active pattern AP between the pair of word lines WL. For example, the upper contact pattern DC may be connected to the common source region of each active pattern AP. The upper contact pattern DC may penetrate the second etch stop layer 133 and the second interlayer insulating layer 131. The upper contact patterns DC may be arranged in a zigzag manner in a plan view. The width of the upper contact pattern DC may be greater than the width of each active pattern AP. The upper contact pattern DC may include a doped semiconductor material (e.g., doped silicon and/or doped germanium, etc.), a conductive metal nitride (e.g., titanium nitride and/or tantalum nitride, etc.), a metal (e.g., one or more of tungsten, titanium, tantalum, etc.), and a metal-semiconductor compound (e.g., one or more of tungsten silicide, cobalt silicide, titanium silicide, etc.).

A third interlayer insulating layer 141 and a third etch stop layer 143 may be sequentially stacked on the second etch stop layer 133.

A bit line contact plug PLG may pass through the third etch stop layer 143 and the third interlayer insulating layer 141 to be connected to the upper contact pattern DC.

Bit lines BL may be disposed or arranged on the third etch stop layer 143. For example, the bit lines BL may be positioned at a higher level than the capacitors CAP and the word lines WL from the top surface of the semiconductor substrate 100. The bit lines BL may extend in the second direction D2 across the active patterns AP and the word lines WL on the third etch stop layer 143. The bit lines BL may be in contact with top surfaces of the bit line contact plugs PLG arranged in the second direction D2, respectively. The bit lines BL may have a line width smaller than a line width of the word lines WL.

The bit lines BL may include, for example, a metal layer such as one or more of copper, aluminum, cobalt, titanium, nickel, tungsten, tantalum, and molybdenum and a metal nitride layer such as one or more of a titanium nitride layer (TiN), a titanium silicon nitride layer (TiSiN), titanium aluminum, a nitride layer (TiAlN), a tantalum nitride layer (TaN), a tantalum silicon nitride layer (TaSiN), a tantalum aluminum nitride layer (TaAlN), and a tungsten nitride layer (WN).

Shielding lines SH may be provided between the bit lines BL adjacent to each other, respectively. The shielding lines SH may extend in the first direction D1 in parallel with the bit lines BL. The shielding lines SH may be horizontally spaced apart from the bit lines BL to be provided in a fourth interlayer insulating layer 151. The shielding lines SH may include a conductive material such as metal. For example, during operation a ground voltage may be applied to the shielding lines SH, and the shielding lines SH may reduce a coupling capacitance between the bit lines BL.

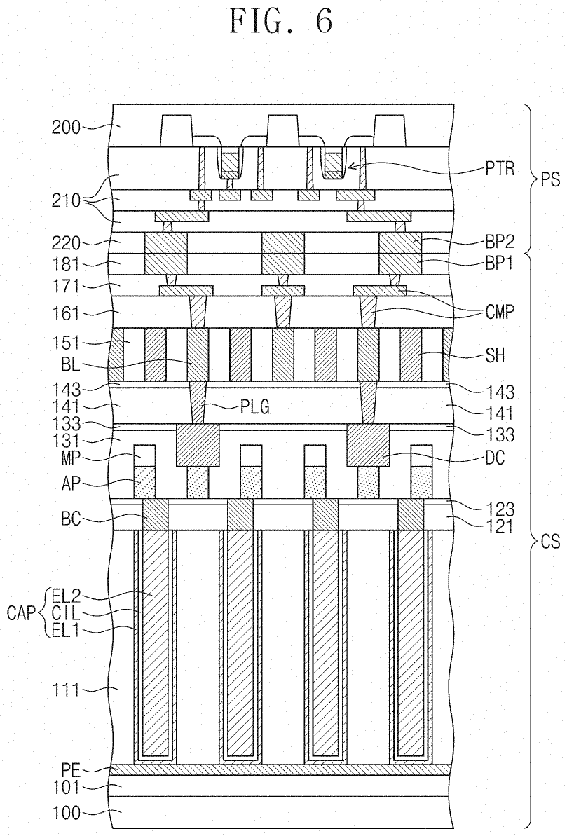

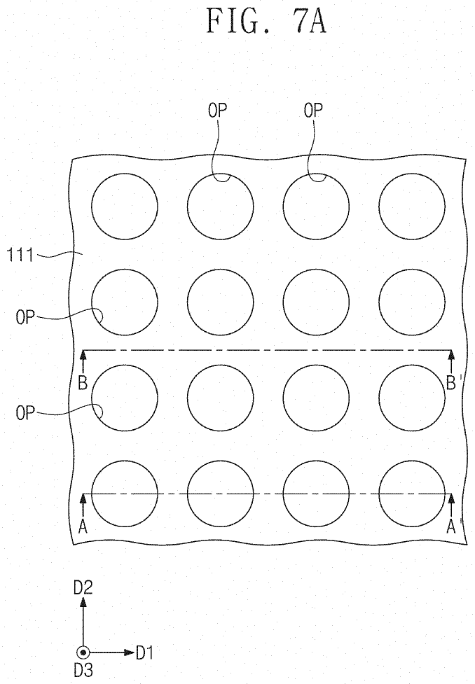

FIG. 6 is a cross-sectional view of a semiconductor memory device according to various example embodiments of inventive concepts.

Referring to FIG. 6, a semiconductor memory device may include a cell array structure CS including first bonding pads BP1 and a peripheral circuit structure PS including second bonding pads BP2 bonded to the first bonding pads BP1.

In detail, the cell array structure CS may include a data storage layer including capacitors CAP, a switching element layer including transistors, and a wiring layer including bit lines, on a first semiconductor substrate 100, as described with reference to FIG. 2.

The cell array structure CS includes substantially the same components as the semiconductor memory device described with reference to FIGS. 4A, 4B, and 4C, and a description of the same components will be omitted.

The first bonding pads BP1 may be provided on the uppermost layer of the cell array structure CS. The bit lines BL of the cell array structure CS may be electrically connected to the first bonding pads BP1 through cell metal structures CMP, respectively. The cell metal structures CMP may include at least two or more metal patterns that are vertically stacked and connected to each other, and metal plugs that connect the metal patterns. The cell metal structures CMP may be disposed in upper insulating layers 161 and 171. The first bonding pads BP1 may be disposed in the uppermost insulating layer 181. The first bonding pads BP1 may include, for example, copper (Cu), aluminum (Al), nickel (Ni), cobalt (Co), tungsten (W), titanium (Ti), tin (Sn), or an alloy thereof.

The peripheral circuit structure PS may include a core and peripheral circuits PTR formed on a second semiconductor substrate 200. The core and peripheral circuits PTR may include row and column decoders (2 and 4 in FIG. 1), a sense amplifiers (3 in FIG. 1), and a control logic (5 in FIG. 1) described with reference to FIG. 1.

The peripheral circuit structure PS may include peripheral insulating layers 210 stacked on the second semiconductor substrate 200, and second bonding pads BP2 disposed in the uppermost peripheral insulating layer 210. The second bonding pads BP2 may have substantially the same size and arrangement as the first bonding pads BP1. The second bonding pads BP2 may or may not include the same metal material as the first bonding pads BP1. The second bonding pads BP2 may include, for example, copper (Cu), aluminum (Al), nickel (Ni), cobalt (Co), tungsten (W), titanium (Ti), tin (Sn), or an alloy thereof.

The second bonding pads BP2 may be electrically connected to the core and the peripheral circuits PTR through peripheral metal structures provided in the peripheral insulating layers 210. The peripheral metal structures may include at least two or more metal patterns that are vertically stacked and connected to each other, and metal plugs connecting the metal patterns.

The semiconductor memory device according to various example embodiments of inventive concepts, after the cell array structure CS including the memory cells is formed on the first semiconductor substrate 100, and the peripheral circuit structure PS including the core and the peripheral circuits PTR is formed on the second semiconductor substrate 200 different from the first semiconductor substrate 100, may be formed by connecting the first semiconductor substrate 100 and the second semiconductor substrate 200 to each other in a bonding method. For example, the first bonding pads BP1 of the cell array structure CS and the second bonding pads BP2 of the peripheral circuit structure PS may be electrically and physically connected to each other by the bonding method. For example, the first bonding pads BP1 may be in direct contact with the second bonding pads BP2.

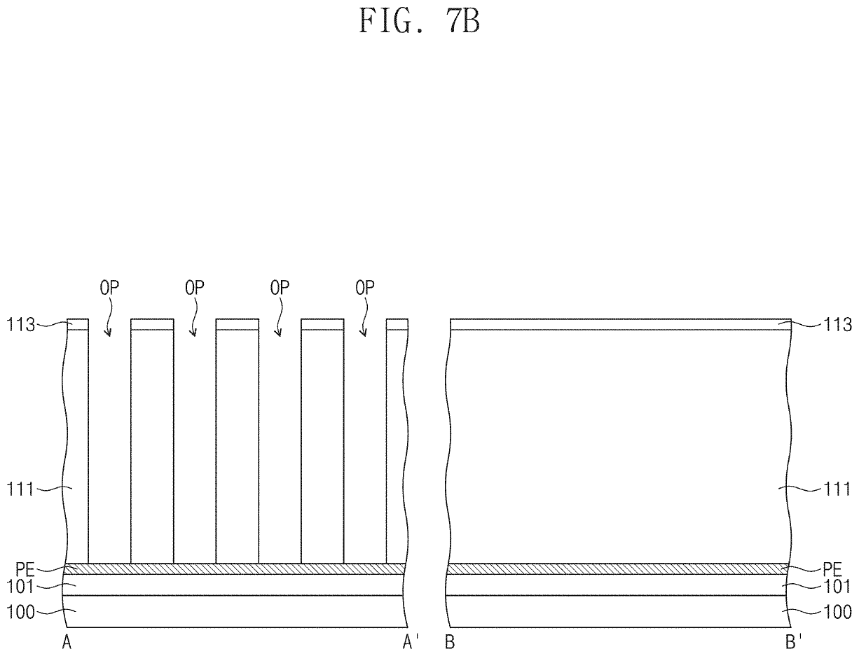

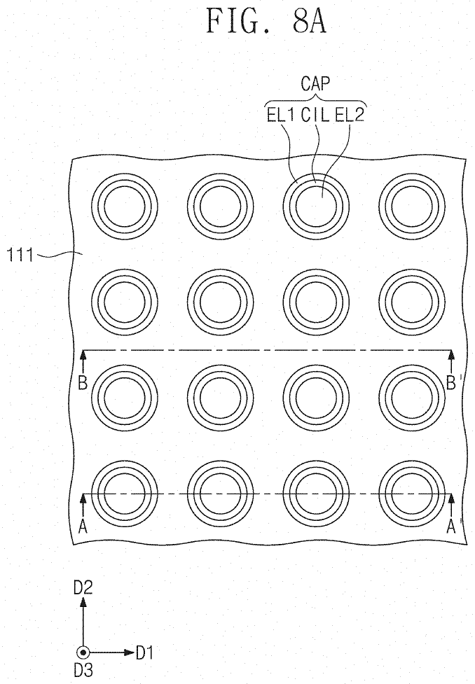

FIGS. 7A, 8A, 9A, 10A, 11A, and 12A are plan views illustrating a method of manufacturing or fabricating a semiconductor memory device according to various embodiments of inventive concepts. FIGS. 7B, 8B, 9B, 10B, 11B, and 12B are cross-sectional views illustrating a method of manufacturing a semiconductor memory device according to various embodiments of inventive concepts and are cross-sectional views taken along lines A-A′ and B-B′ of FIGS. 7A to 12A.

Referring to FIGS. 7A and 7B, a lower insulating layer 101 and a plate conductive layer PE may be sequentially stacked on a semiconductor substrate 100.

The plate conductive layer PE may cover a top surface of the lower insulating layer 101. The plate conductive layer PE may have a plate shape extending in a first direction D1 and a second direction D2. The plate conductive layer PE may include, for example, doped polysilicon, metal, conductive metal nitride, conductive metal silicide, conductive metal oxide, or a combination thereof. The plate conductive layer PE may be formed of, for example, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but is not limited thereto. The plate conductive layer PE may be formed using a deposition process such as chemical vapor deposition (CVD) and/or physical vapor deposition (PVD).

A mold structure including a lower mold layer 111 and a lower support layer 113 sequentially stacked on the plate conductive layer PE may be formed.

The lower mold layer 111 may be formed of, for example, a silicon oxide layer and/or a silicon oxynitride layer. The lower mold layer 111 may be formed using a deposition process such as chemical vapor deposition (CVD) and/or physical vapor deposition (PVD). The lower support layer 113 may be formed of a material having etch selectivity, e.g. a slower etch rate, with respect to the lower mold layer 111. In some example embodiments, the lower support layer 113 may be formed using one or more of SiN, SiCN, TaO, and TiO₂. In some example embodiments, the lower support layer 113 may be omitted.

After forming the mold structure, openings OP may be formed by patterning the mold structure. The openings OP may expose the plate conductive layer PE. The forming of the openings OP may be formed by forming a mask pattern (not shown) having openings on the lower support layer 113 and anisotropically etching the lower support layer 113 and the lower mold layer 111 using a mask pattern. The openings OP may be formed to be spaced apart from one another at regular intervals in the first direction D1 and the second direction D2.

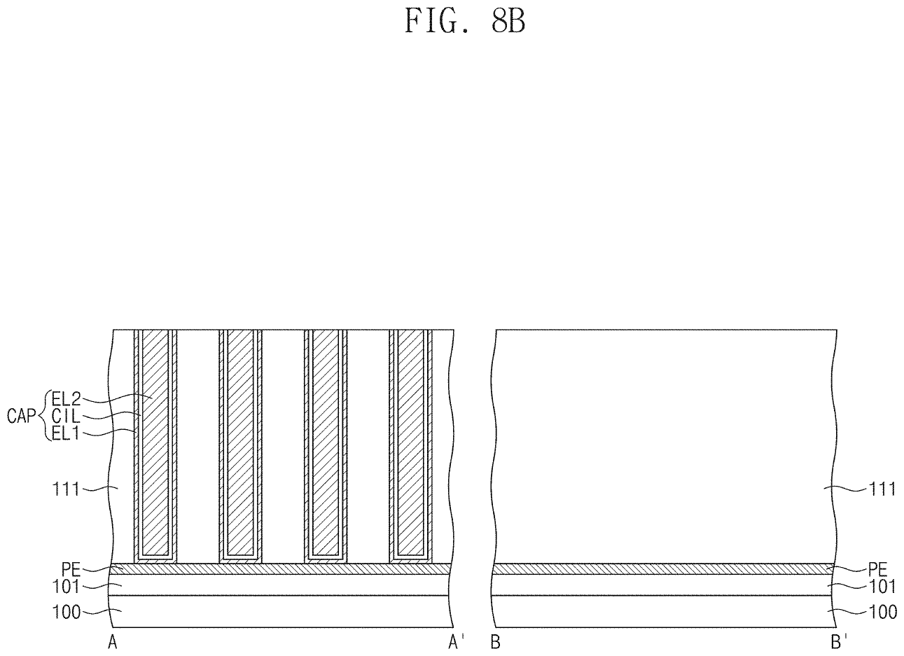

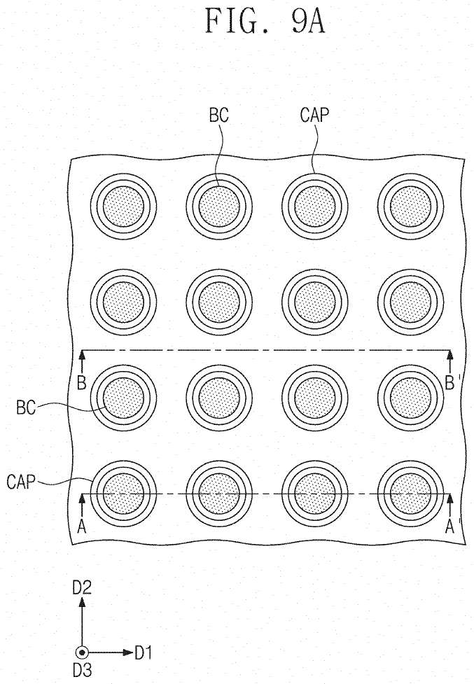

Referring to FIGS. 8A and 8B, capacitors CAP may be formed as data storage devices in the openings OP. In detail, forming the capacitors CAP may include forming first electrodes EL1 in the openings OP, forming a capacitor dielectric layer CIL conformally covering inner walls of the first electrodes ELL and forming second electrodes EL2 in openings in which the capacitor dielectric layer CIL is formed.

Here, the forming of the first electrodes EL1 may include depositing a first electrode layer with a uniform thickness to cover a surface of the mold structure in which the openings are formed, depositing the capacitor dielectric layer with a uniform thickness on the first electrode layer, forming a second electrode layer to fill the openings in which the first electrode layer and the capacitor dielectric layer are deposited, and sequentially etching the second electrode layer, the capacitor dielectric layer, and the first electrode layer to expose a top surface of the mold layer 111.

The first electrode layer, the capacitor dielectric layer CIL, and the second electrode layer may be formed using a layer-forming technology with a good or excellent property of step coverage, such as one or more of chemical vapor deposition (CVD), physical vapor deposition (PVD), or atomic layer deposition (ALD).

The capacitor dielectric layer CIL may be formed of a high dielectric material and may include single layer selected from the group consisting of a dielectric material, for example, a metal oxide such as HfO₂, ZrO₂, Al₂O₃, La₂O₃, Ta₂O₃, and TiO₂, and a perovskite-structured dielectric material such as SrTiO₃ (STO), (Ba,Sr)TiO₃ (BST), BaTiO₃, PZT, PLZT, or a combination of these layers.

The first electrodes EL1 and the second electrodes EL2 may include, for example, a high melting point metal layer such as one or more of cobalt, titanium, nickel, tungsten and molybdenum and/or a metal nitride layer such as a titanium nitride layer (TiN), a titanium silicon nitride layer (TiSiN), a titanium aluminum nitride layer (TiAlN), a tantalum nitride layer (TaN), a tantalum silicon nitride layer (TaSiN), a tantalum aluminum nitride layer (TaAlN), and a tungsten nitride layer (WN).

According to various example embodiments, heat treatment processes may be performed at a high temperature to increase capacitance when forming capacitors.

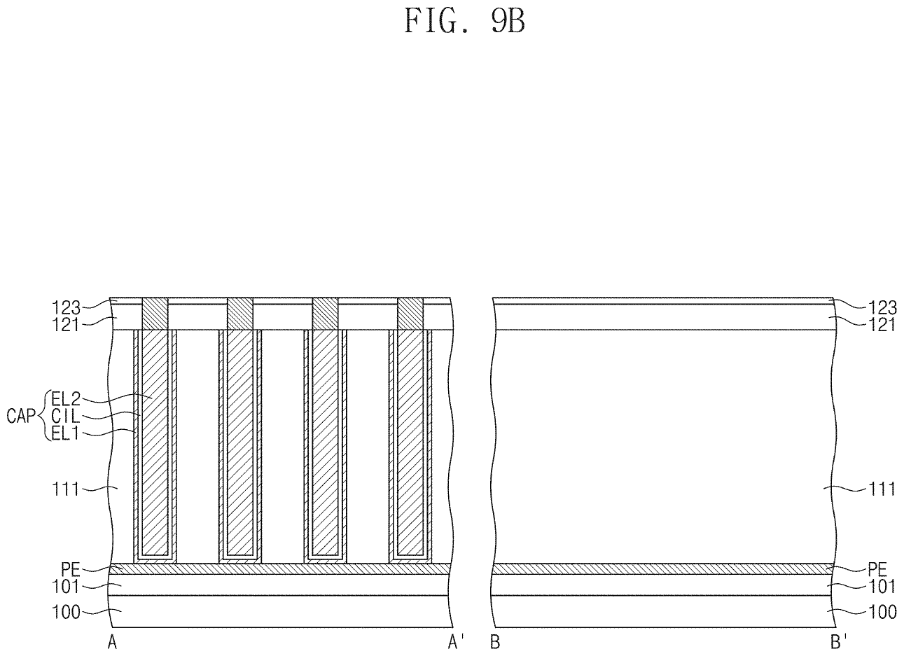

Referring to FIGS. 9A and 9B, a first interlayer insulating layer 121 and a first etch stop layer 123 may be sequentially formed on the lower mold layer 111. The first interlayer insulating layer 121 may cover top surfaces of the first electrodes ELL top surfaces of the second electrodes EL2, and a top surface of the capacitor dielectric layer CIL.

Subsequently, lower contact patterns BC may be formed through the first interlayer insulating layer 121 and the first etch stop layer 123 and respectively connected to the second electrodes EL2. The lower contact patterns BC may have, for example, a rectangular, square, circular, or oval shape. The lower contact patterns BC may be in contact with parts of the second electrodes EL2, respectively. The lower contact patterns BC may be disposed to be spaced apart from one another in the first direction D1 and the second direction D2.

Forming the lower contact patterns BC may include forming contact holes penetrating the first interlayer insulating layer 121 to expose the second electrodes EL2, respectively, depositing a conductive layer filling the contact holes, and etching the conductive layer to expose the first etch stop layer 123.

As an example, although it has been described that the lower contact pattern BC is formed after forming the interlayer insulating layer 121, inventive concepts is not limited thereto, and after forming the lower contact pattern BC, the interlayer insulating layer 121 may be formed.

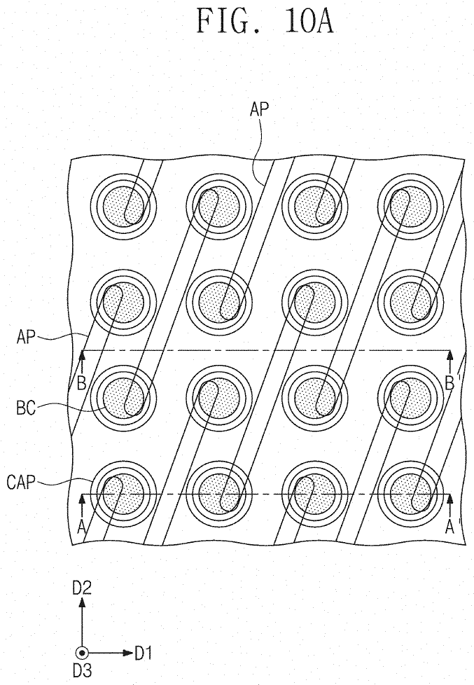

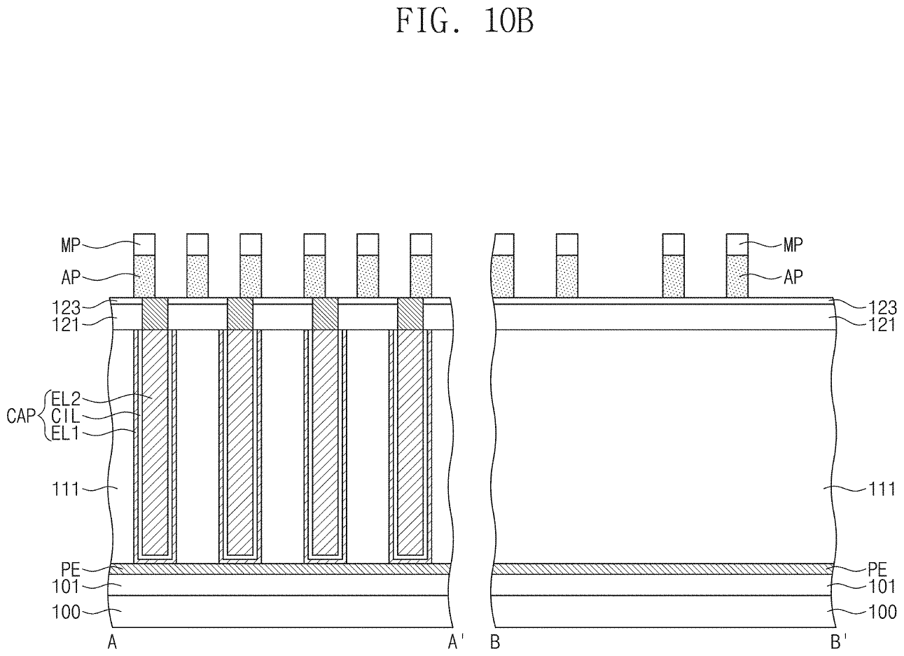

Referring to FIGS. 10A and 10B, active patterns AP and mask patterns MP may be formed on the first etch stop layer 123.

The active patterns AP may be formed in a fin shape on the interlayer insulating layer 121. The active patterns AP may have a rectangular shape (or a bar shape) and may be two-dimensionally arranged in the first direction D1 and the second direction D2 crossing the first direction D1. The active patterns AP may be arranged in a zigzag manner in a plan view, and may have a lengthwise axis in a diagonal direction with respect to the first direction D1 and the second direction D2. It is described that the active patterns AP have the lengthwise axis in the diagonal direction and are arranged in the zigzag manner as an example, but inventive concepts are not limited thereto. The shape and/or the arrangement of the active patterns AP may be variously modified.

Each of the active patterns AP may be in contact with a pair of the lower contact patterns BC. Both ends of each active pattern AP may be in contact with top surfaces of the lower contact patterns BC, and a central part of the active pattern AP may be disposed between the lower contact patterns BC adjacent to each other.

Forming the active patterns AP may include forming an active layer on the first etch stop layer 123, forming the mask patterns MP on the active layer, and anisotropically etching the active layer to expose the first etch stop layer 123 using the hard mask patterns MP as an etch mask. Here, the active layer may be formed using at least one of physical vapor deposition (PVD), thermal chemical vapor deposition (thermal CVD), low pressure chemical vapor deposition (LP-CVD), plasma enhanced chemical vapor deposition (PE-CVD), or atomic layer deposition (ALD) techniques. The active patterns AP may include a semiconductor material, for example, silicon, germanium, silicon-germanium, or an oxide semiconductor.

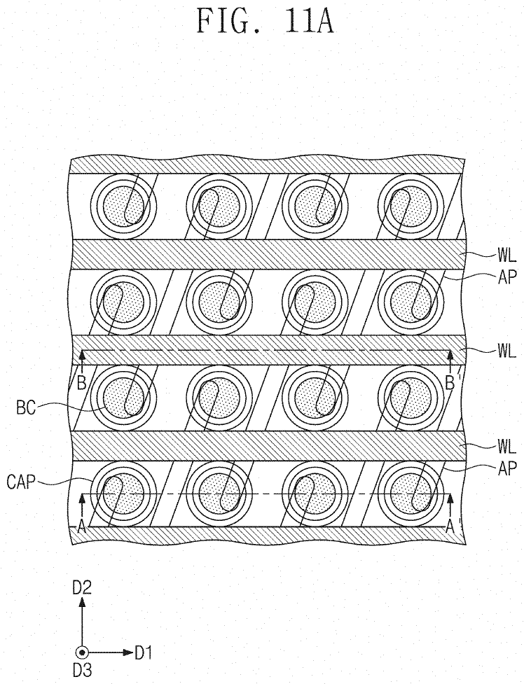

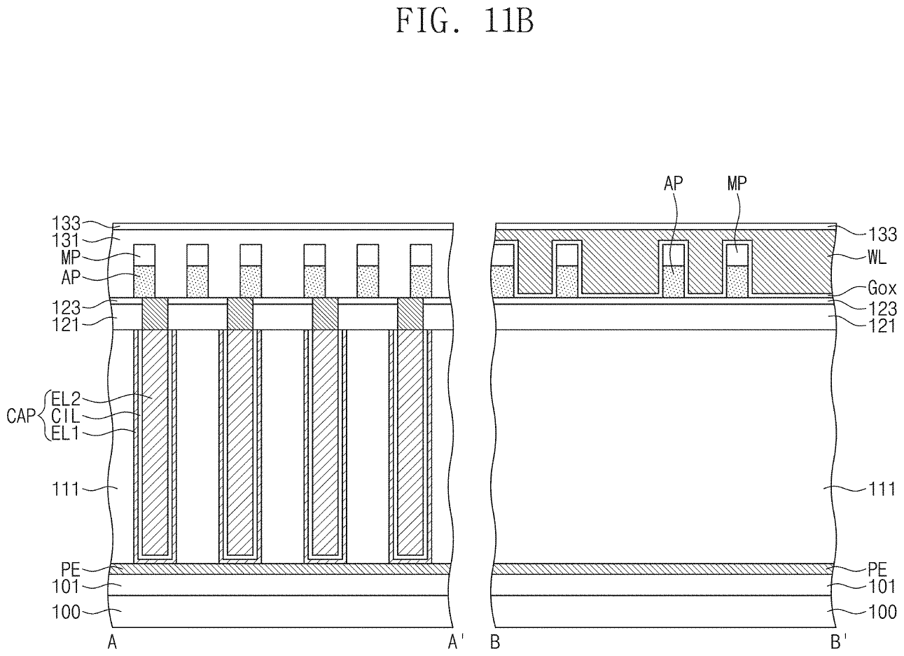

Referring to FIGS. 11A and 11B, a second interlayer insulating layer 131 covering the active patterns AP may be formed on the first etch stop layer 123.

Subsequently, a ferroelectric layer Gox and word lines WL extending in the first direction D1 may be formed in the second interlayer insulating layer 131. Forming the word lines WL may include forming trenches extending in the first direction D1 by patterning the second interlayer insulating layer 131, sequentially depositing the ferroelectric layer Gox and a gate conductive layer in the trenches, and sequentially anisotropically etching the ferroelectric layer Gox and the gate conductive layer to expose the top surface of the second interlayer insulating layer 131. Here, a pair of trenches may cross each active pattern AP, and the trenches may expose sidewalls of channel regions of the active patterns AP and the top surface of the mask pattern MP.

The ferroelectric layer Gox and gate conductive layer may be formed using at least one physical vapor deposition (PVD), thermal chemical vapor deposition (thermal CVD), low pressure chemical vapor deposition (LP-CVD), plasma enhanced chemical vapor deposition (PE-CVD), or atomic layer deposition (ALD) techniques. The ferroelectric layer Gox may include a ferroelectric material having negative capacitance characteristics, and the gate conductive layer may include a metal material.

The ferroelectric layer Gox may cover both sidewalls and top surfaces of the active patterns AP with a substantially uniform thickness. The gate conductive layer may completely fill the trenches in which the ferroelectric layer Gox is formed.

After forming the word lines WL, a second etch stop layer 133 may be formed on the second interlayer insulating layer 131. The second etch stop layer 133 may cover a top surface of the second interlayer insulating layer 131 and top surfaces of the word lines WL. The second etch stop layer 133 may be formed of an insulating material different from an insulating material of the second interlayer insulating layers 131.

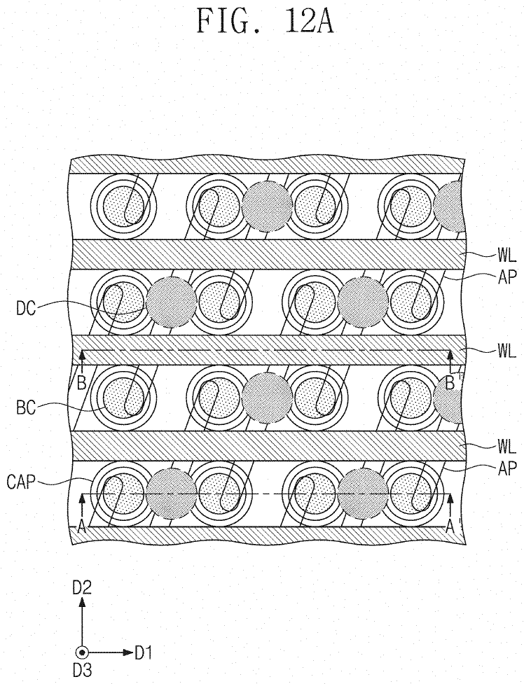

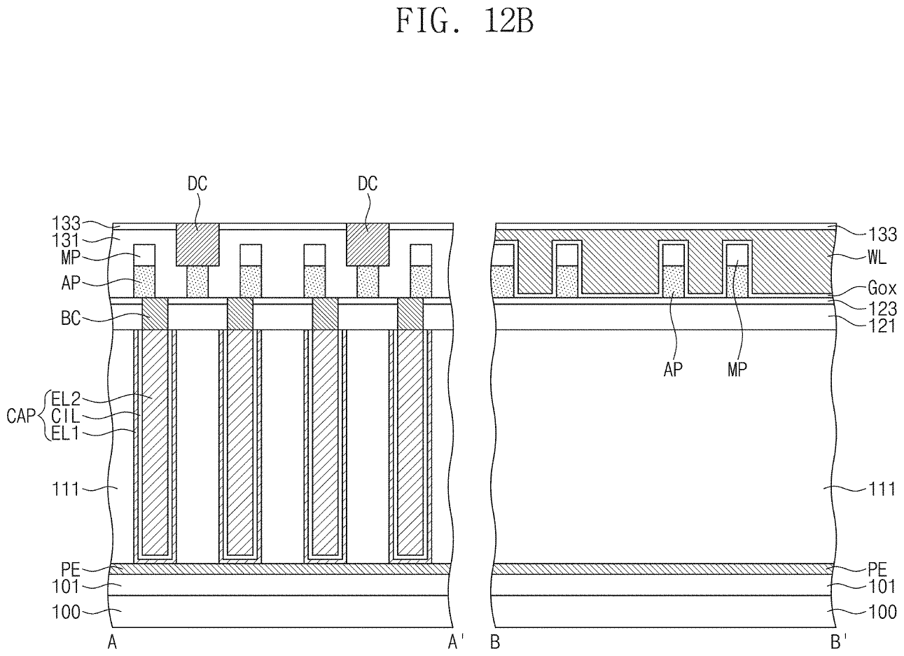

Referring to FIGS. 12A and 12B, upper contact patterns DC penetrating the second interlayer insulating layer 131 and the second etch stop layer 133 may be formed. Forming the upper contact patterns DC may include forming a mask pattern (not shown) on the second etch stop layer 133, anisotropically etching the second etch stop layer 133 and the second interlayer insulating layer 131 to form contact holes exposing central parts of the active patterns AP, depositing a conductive layer filling the contact holes, and exposing the second etch stop layer 133 by anisotropically etching the conductive layer.

The upper contact patterns DC may be in contact with top surfaces of central parts of the active patterns AP, respectively. Each of the upper contact patterns DC may be disposed between a pair of word lines WL adjacent to each other on each active pattern AP.

Subsequently, referring back to FIGS. 4A, 4B, and 4C, a third interlayer insulating layer 141 and a third etch stop layer 143 may be sequentially stacked on the second etch stop layer 133.

Contact holes may be formed through the third etch stop layer 143 and the third interlayer insulating layer 141 to expose the upper contact patterns DC, and a conductive material may be buried in the contact holes to form bit line contact plugs PLG.

Thereafter, a fourth interlayer insulating layer 151 may be formed on the third etch stop layer 143, and the bit lines BL and the shielding lines SH may be formed in the interlayer insulating layer 151 using a damascene process. For example, trenches extending in the second direction D2 may be formed by patterning the fourth interlayer insulating layer 151 and may be filled with a metal material to form the bit lines BL and the shielding lines SH.

According to various example embodiments of inventive concepts, the transistors of the memory cell may include the ferroelectric layer having the negative capacitance characteristics, and thus the subthreshold swing value of the transistor may be reduced. Accordingly, in the transistor, the off current (e.g., leakage current) may be reduced, and/or the gate voltage may be reduced. Accordingly, the standby power and/or operation power of the transistor may be reduced.

Alternatively or additionally, the transistors including the ferroelectric layer may be formed after the forming of the capacitors in which the high-temperature thermal process is performed, and thus the thermal budget of the ferroelectric layer may be reduced, and/or the change in the material properties of the ferroelectric layer may be reduced or minimized.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

While various example embodiments of inventive concepts have been particularly shown and described, it will be understood by one of ordinary skill in the art that variations in form and detail may be made therein without departing from the spirit and scope of the attached claims. Furthermore, example embodiments are not necessarily mutually exclusive. For example, some example embodiments may include one or more features described with reference to one or more figures, and may also include one or more other features described with reference to one or more other figures.

What is claimed is:

1. A semiconductor memory device comprising:
a semiconductor substrate;
a data storage layer including capacitors arranged on the semiconductor substrate;
a switching element layer on the data storage layer and including transistors connected to respective ones of the capacitors; and
a wiring layer on the switching element layer and including bit lines connected to respective ones of the transistors,
wherein the respective transistors include an active pattern, a word line that crosses the active pattern such that the word line surrounds a first sidewall, a second sidewall and a top surface of the active pattern, and a ferroelectric layer between the word line and the active patter.

2. The semiconductor memory device of claim 1, wherein
the word line extends in a first direction that is parallel to a top surface of the semiconductor substrate,
the bit lines extends in a second direction that is parallel to the top surface of the semiconductor substrate and intersects the first direction, and
the active pattern has a lengthwise axis in a third direction that is parallel to the top surface of the semiconductor substrate and intersects the first and second directions.

3. The semiconductor memory device of claim 1, further comprising:
shielding lines in regions between the bit lines.

4. The semiconductor memory device of claim 1, further comprising:
a lower contact pattern contacting a bottom surface of the active pattern at one side of the word line; and
an upper contact pattern contacting a top surface of the active pattern at an opposite side of the word line.

5. The semiconductor memory device of claim 4, wherein
one of the capacitors is connected to the lower contact pattern, and
one of the bit lines is connected to the upper contact pattern.

6. The semiconductor memory device of claim 1, wherein the capacitors includes:
a plate electrode on the semiconductor substrate;
first electrodes two-dimensionally arranged on the plate electrode;
second electrodes on the first electrodes; and
capacitor dielectric layers between the first electrodes and the second electrodes, respectively.

7. The semiconductor memory device of claim 6, wherein each of the first electrodes includes a bottom part contacting the plate electrode and a sidewall part extending vertically from the bottom part.

8. The semiconductor memory device of claim 1, wherein the ferroelectric layer includes at least one of HfO₂, Si-doped HfO₂ (HfSiO₂), Al-doped HfO₂ (HfAlO₂), HfSiON, HfZnO, HfZrO₂, ZrO₂, ZrSiO₂, HfZrSiO₂, ZrSiON, LaAlO₂, HfDyO₂, or HfScO₂.

9. The semiconductor memory device of claim 1, further comprising:
a gate dielectric layer between the ferroelectric layer and the active pattern.

10. The semiconductor memory device of claim 1, further comprising:
a gate dielectric layer between the ferroelectric layer and the active pattern; and
a sub-gate electrode between the ferroelectric layer and the gate dielectric layer.

11. A semiconductor memory device comprising:
a plate electrode on a semiconductor substrate;
first electrodes two-dimensionally arranged on the plate electrode;
second electrodes on the first electrodes;
capacitor dielectric layers between the first electrodes and the second electrodes, respectively;
an active pattern having a lengthwise axis parallel to a top surface of the semiconductor substrate and connected to one of the second electrodes;
a word line crossing the active pattern;
a ferroelectric layer between the word line and the active pattern; and
a bit line crossing the word line and connected to the active pattern.

12. The semiconductor memory device of claim 11, wherein
the word line extends in a first direction parallel to the top surface of the semiconductor substrate,
the bit line extends in a second direction parallel to the top surface of the semiconductor substrate and perpendicular to the first direction, and
the first electrodes are spaced apart from one another by a same first distance in the first direction and a same second distance in the second direction.

13. The semiconductor memory device of claim 11, further comprising:
a shield line extending parallel to the bit line and located at a same level as the bit line.

14. The semiconductor memory device of claim 11, wherein each of the first electrodes includes a bottom part contacting the plate electrode and a sidewall part extending vertically from the bottom part.

15. The semiconductor memory device of claim 11, wherein the word line crosses both sidewalls of the active pattern.

16. The semiconductor memory device of claim 11, further comprising:
a lower contact pattern connecting one of the second electrodes to the active pattern at one side of the word line; and
an upper contact pattern connecting the active pattern to the bit line at an opposite side of the word line.

17. The semiconductor memory device of claim 16, wherein a width of the active pattern is less than a width of the upper contact pattern and is less than a width of the lower contact pattern.

18. A semiconductor memory device comprising:
a plate electrode on a semiconductor substrate;
first electrodes in a mold layer covering the plate electrode and connected to the plate electrode;
second electrodes on the first electrodes;
capacitor dielectric layers between the first electrodes and the second electrodes, respectively;
lower contact patterns passing through a first interlayer insulating layer covering the first and second electrodes on the mold layer, the lower contact patterns connected to the second electrodes, respectively;
active patterns on the first interlayer insulating layer and having a lengthwise axis parallel to a top surface of the semiconductor substrate, each of the active patterns connected to a first pair of the lower contact patterns;
word lines extending in a first direction and crossing the active patterns on the first interlayer insulating layer;
a ferroelectric layer between the word lines and the active patterns;
upper contact patterns connected to the active patterns between the word lines;
bit lines extending in a second direction and crossing the word lines, the bit lines connected to the upper contact patterns; and
shielding lines extending in the second direction and respectively provided in regions between the bit lines.

19. The semiconductor memory device of claim 18, wherein the lower contact patterns are in contact with top surfaces of the second electrodes.

20. The semiconductor memory device of claim 18, wherein the first electrodes are spaced apart from one another by a same first distance in the first direction a same second distance in the second direction.
